(19) United States
(12) Patent Application Publication
(10) Pub. No.: US 2014/0061439 A1
(43) Pub. Date: Mar. 6, 2014

(54) SOLID-STATE IMAGING DEVICE, ELECTRONIC APPARATUS WITH SOLID-STATE IMAGING DEVICE, AND DISPLAY DEVICE

(71) Applicant: Sony Corporation, Tokyo (JP)

(72) Inventor: Atsushi Toda, Kanagawa (JP)

(73) Assignee: Sony Corporation, Tokyo (JP)

(21) Appl. No.: 14/014,113

(22) Filed: Aug. 29, 2013

(30) Foreign Application Priority Data
Sep. 6, 2012 (JP) 2012-196439

(51) Int. Cl. F21V 7/10; H05B 33/22; H01L 31/0232; G01J 1/04

(52) U.S. Cl. CPC F21V 7/10; G01J 1/0414; H05B 33/22; H01L 31/0232
USPC 250/208.1; 313/113; 313/504; 257/432

(57) ABSTRACT

There is provided a solid-state imaging device including a photoelectric conversion unit, and a reflecting plate that includes a first portion that is provided on a side opposing a light incidence side with respect to the photoelectric conversion unit and formed at a center of a region in which light beams are collected, and a second portion that is formed on a boundary of adjacent regions to be convex on the incidence side with respect to the first portion, and collects reflected light beams within the regions by generating a phase difference between reflected light beams on the first portion and reflected light beams on the second portion.

### BACKGROUND

The present technology relates to a solid-state imaging device, and an electronic apparatus with the solid-state imaging device. In addition, the present technology relates to a display device that performs display using organic EL devices, or the like.

As mechanism to enhance sensitivity of a solid-state imaging device, there is a method in which a reflecting plate is disposed on a circuit side opposing a light incident side to improve sensitivity of, particularly, a backside illumination type CIS (CMOS image sensor) (refer to, for example, Japanese Unexamined Patent Application Publication No. 2010-147333, Japanese Unexamined Patent Application Publication No. S58-122775, and Japanese Unexamined Patent Application Publication No. 2007-027604).

However, mere disposition of a flat reflecting plate is sometimes not sufficient for enhancing sensitivity or contributes to color mixing because reflected light is incident on some near pixels.

In order to resolve the above-described problem, making a reflecting surface of the reflecting plate to be a spherical surface, or the like has been proposed (refer to, for example, Japanese Unexamined Patent Application Publication No. 2010-118412, and Japanese Unexamined Patent Application Publication No. 2010-056167).

On the other hand, there is a device aimed at enhancement of sensitivity thereof using reflection also in the field of displays represented by organic EL (electro-luminescence).

Particularly, in a display configured to separate colors by emitting white light and causing the light to pass through color filters of three colors of RGB, if reflected light passes through adjacent pixels and then causes color mixing, the color mixing brings a problem in color reproducibility.

### SUMMARY

As described above, sensitivity is enhanced by providing a reflecting plate, but at the same time, color mixing also increases.

In addition, if a reflecting surface of the reflecting plate is set to be a curved surface such as a spherical surface, or the like, there are disadvantages in that the process of producing the reflecting plate becomes complicated, and a cost thereof also increases.

It is desirable to provide a solid-state imaging device and a display device that have a reflecting plate that can attain enhancement of sensitivity and improvement of use efficiency by reflecting incident light, and suppress color mixing. In addition, it is desirable to provide an electronic apparatus with such a solid-state imaging device.

According to an embodiment of the present technology, there is provided a solid-state imaging device including a photoelectric conversion unit, and a reflecting plate that includes a first portion that is provided on a side opposing a light incidence side with respect to the photoelectric conversion unit and formed at a center of a region in which light beams are collected, and a second portion that is formed on a boundary of adjacent regions to be convex on the incidence side with respect to the first portion, and collects reflected light beams within the regions by generating a phase difference between reflected light beams on the first portion and reflected light beams on the second portion.

According to an embodiment of the present disclosure, there is provided an electronic apparatus including an optical lens, a solid-state imaging device, and a signal processing circuit that processes signals output from the solid-state imaging device.

According to an embodiment of the present technology, there is provided a display device including a light emitting unit, and a reflecting plate that is provided on the back side of the light emitting unit, includes a first portion formed at a center of a region in which light beams are collected and a second portion that is formed on a boundary of adjacent regions to be convex on a side of the light emitting unit with respect to the first portion, and causes reflected light beams to be collected within the regions so as to be projected in front of the light emitting unit by generating a phase difference between reflected light beams on the first portion and reflected light beams on the second portion.

According to the embodiment of the solid-state imaging device of the present technology described above, reflected light beams are collected within the region by generating a phase difference between reflected light beams on the first portion of the reflecting plate and reflected light beams on the second portion of the reflecting plate.

Thus, the reflected light beams can be collected at the centers of the regions using the reflected plate, and leakage of the reflected light beams to adjacent regions can thereby be prevented.

According to the embodiment of the electronic apparatus of the present technology described above, since the solid-state imaging device according to an embodiment of the present technology is provided, reflected light beams can be collected at the centers of the regions in the solid-state imaging device, and leakage of the reflected light beams to adjacent regions can thereby be prevented.

According to the embodiment of the display device of the present technology described above, reflected light beams are collected within the regions by generating a phase difference between reflected light beams on the first portion of the reflecting plate and reflected light beams on the second portion of the reflecting plate.

Thus, the reflected light beams can be collected at the centers of the regions using the reflected plate, and leakage of the reflected light beams to adjacent regions can thereby be prevented.

According to the embodiments of the present technology described above, the reflected light beams can be collected at the centers of the regions using the reflected plate, and leakage of the reflected light beams to adjacent regions can thereby be prevented.

Accordingly, sensitivity of the solid-state imaging device can be efficiently enhanced without increasing color mixing in which light beams are incident on adjacent pixels caused by leakage of light beams to the adjacent regions.

In addition, in the display device, use efficiency of light emitted from the light emitting unit can be enhanced, and color mixing in which light beams are incident on adjacent pixels can be prevented.

Therefore, according to the embodiment of the present technology, the solid-state imaging device and the electronic apparatus with the solid-state imaging device that have high sensitivity and obtain images with satisfactory color reproducibility and image quality can be realized.

In addition, according to the embodiment of the present technology, the display device that has high light use efficiency and can display images with satisfactory color reproducibility and image quality can be realized.

### BRIEF DESCRIPTION OF THE DRAWINGS

FIG. 1 is a schematic configuration diagram (plan diagram) of a solid-state imaging device according to a first embodiment;

FIG. 2 is a cross-sectional view of a pixel region of the solid-state imaging device according to the first embodiment;

FIG. 3 is a plan layout diagram of a reflecting plate of the solid-state imaging device according to the first embodiment;

FIGS. 4A and 4B are cross-sectional diagrams of pixel regions of a solid-state imaging device according to a second embodiment;

FIG. 5 is a plan layout diagram of a reflecting plate of the solid-state imaging device according to the second embodiment;

FIG. 6 is a schematic configuration diagram (cross-sectional diagram) of a solid-state imaging device according to a third embodiment;

FIG. 7 is a schematic configuration diagram (block diagram) of an electronic apparatus according to a fourth embodiment;

FIG. 8 is a schematic configuration diagram (cross-sectional diagram) of a display device according to a fifth embodiment;

FIGS. 9A and 9B are diagrams for describing specular reflection in geometric optics;

FIGS. 10A and 10B are cross-sectional diagrams of reflecting plates that collect reflected light using geometric optics;

FIGS. 11A and 11B are diagrams for describing the relationship between the size of a pixel and presence/absence of light condensing;

FIGS. 12A and 12B are diagrams showing a structure for performing a simulation of a configuration of a solid-state imaging device according to the present technology and the result thereof;

FIG. 13 is a diagram showing wavefronts of the same phases indicated by dashed lines in the enlarged diagram of FIG. 12B showing the result of the simulation;

FIGS. 14A to 14C are diagrams showing examples of the structure of the reflecting plate according to the present technology;

FIGS. 15A and 15B are diagrams showing other examples of the structure of the reflecting plate according to the present technology;

FIG. 16 is a diagram showing another example of the structure of the reflecting plate according to the present technology;

FIGS. 17A to 17D are diagrams showing examples of the structure of the reflecting plate according to the present technology;

FIG. 18 is a diagram showing still another example of the structure of the reflecting plate according to the present technology;

FIGS. 19A and 19B are diagrams showing a structure for performing a simulation of a configuration in which the reflecting plate is asymmetric and the result thereof; and

FIGS. 20A to 20C are diagrams showing examples of the structure of the reflecting plate according to the present technology in which the reflecting plate is asymmetric.

### DETAILED DESCRIPTION OF THE EMBODIMENT(S)

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

Hereinafter, preferred embodiments for implementing the present technology (hereinafter, referred to as embodiments) will be described.

It should be noted that description will be provided in the following order.

1. Overview of the present technology

2. First embodiment (solid-state imaging device)

3. Second embodiment (solid-state imaging device)

4. Third embodiment (solid-state imaging device)

5. Fourth embodiment (electronic apparatus with the solid-state imaging device)

6. Fifth embodiment (display device)

### 1. Overview of the Present Technology

First, prior to detailed description of embodiments, an overview of the present technology will be described.

### (Basic Configuration)

In the present technology employing a configuration in which a reflecting plate having convex portions is provided on the side opposing a light incidence side, light beams are collected at the center of a region (one pixel or a plurality of pixels) as a target of light collection, sensitivity is thereby enhanced, and occurrence of color mixing is reduced, and finally an improvement in image quality is attained.

In other words, the reflecting plate is configured to include a first portion formed at the center of the region (one pixel or a plurality of pixels) as a target of light collection and second portions on the boundaries between adjacent regions. The second portions are formed to be convex with respect to the first portion toward the incidence side so as to be convex portions with respect to the first portion.

In addition, as will be described later in detail, reflected light beams can be collected within the region and then collected at the center of the region by generating a phase difference between light reflected on the first portion of the reflecting plate and light reflected on the second portions of the reflecting plate.

### (Difference Between the Related Art and the Present Technology)

A reflecting plate proposed in the related art has a reflecting surface which is, for example, a spherical surface or a curved surface, or which has a cross-section in a trapezoidal shape.

In such a configuration, specular reflection occurs in terms of geometric optics, and thereby light collection is possible.

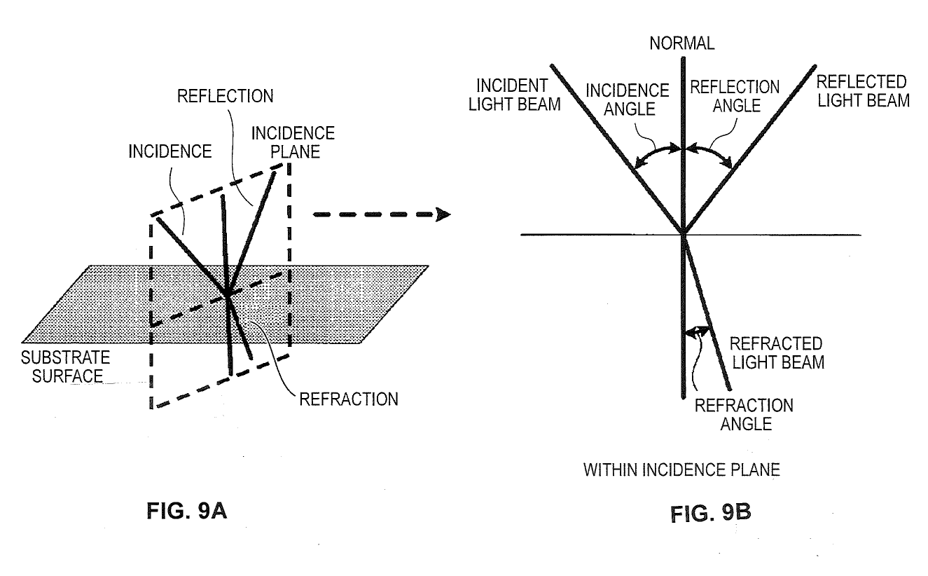

Herein, the specular reflection in geometric optics will be described with reference to FIGS. 9A and 9B.

As shown in FIGS. 9A and 9B, with regard to light incident on a flat substrate surface, a reflected light beam, a refracted light beam, an incidence plane (a plane including all of the incident light beam, the reflected light beam, and the refracted light beam), and a normal (a straight line perpendicular to a substrate surface within the incidence plane) can be defined.

In addition, as shown in FIG. 9B, an angle formed by the incident light beam and the normal (incidence angle) is equal to an angle formed by the reflected light beam and the normal (reflection angle), and accordingly, so-called specular reflection occurs.

In the phenomenon of specular reflection, the incidence plane and the normal can be defined with respect to a substrate surface on which the light is incident in the same manner as above even when the substrate has a curved surface, and the incidence angle is equal to the reflection angle.

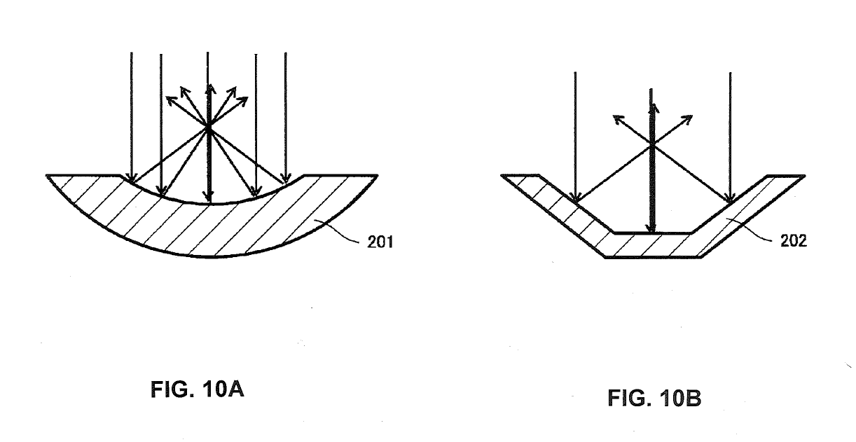

According to this principle, reflected light beams can be collected on a reflecting plate 201 shown in FIG. 10A of which a reflecting surface is a spherical surface or a curved surface, and on a reflecting plate 202 shown in FIG. 10B of which the cross-section is in a trapezoidal shape.

This is a configuration of a reflecting plate using geometric optics proposed in the related art.

Meanwhile, in the present technology, reflected light beams are collected using a phase difference of the light beams, which is based on a principle different from the configuration for collecting light beams using geometric optics described above.

In addition, an effect of the present technology particularly increases as the size of pixels decreases.

This is because geometric optics is not valid and the degree of use of a wave function increases as the size of pixels decreases.

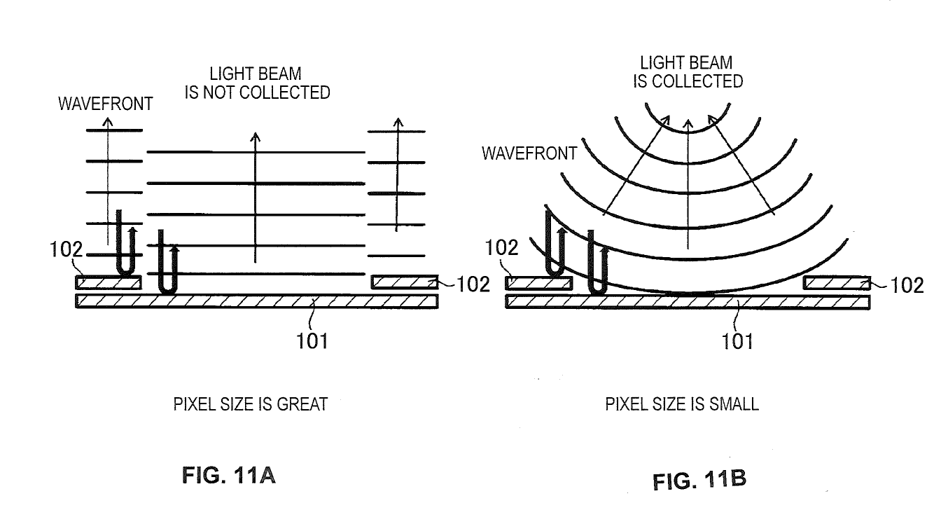

This matter will be described with reference to FIGS. 11A and 11B.

FIGS. 11A and 11B describe the relationship between a pixel size and presence/absence of light collection when a reflecting plate having a first reflecting plate 101 formed in a lower layer over all of the pixels and second reflecting plates 102 formed in an upper layer t the edge portions of pixels (boundaries of adjacent pixels) is configured. The first reflecting plate 101 corresponds to the “first portion of a reflecting plate” described above, and the second reflecting plates 102 correspond to the “second portions of a reflecting plate” described above.

The first reflecting plate 101 is in the lower layer on a far side of light incidence. The second reflecting plates 102 are in the upper layer on a near side of light incidence. The second reflecting plates 102 are convexly formed toward the incidence side with respect to the first reflecting plate 101, forming convex portions.

With the configuration of the reflecting plates, incident light is reflected on the first reflecting plate 101 and the second reflecting plates 102, but reflection positions are different.

When a pixel size is great as shown in FIG. 11A, light beams reflected on the respective reflecting plates at the edge portions and centers of pixels are individually reflected in a direction perpendicular to reflecting surfaces based on specular reflection. In addition, since wavefronts of the reflected light beams are horizontal, the reflected light beams are not collected.

When a pixel size is small as shown in FIG. 11B, wavefronts of reflected light beams are curved due to continuity of wave functions, and resultantly, the reflected light beams are collected.

In other words, since reflection positions are different on the first reflecting plate 101 and the second reflecting plates 102, the phases of the light beams are accordingly, different, light beams reflected on the second reflecting plates 102 on the near side advance quickly, light beams reflected on the first reflecting plate 101 on the far side advance slowly, and as a result, the phases of the light beams exhibit differences.

In addition, when a pixel size is small, as wave functions are continuously connected, reflected light beams having phase differences are connected, and thereby, wavefronts that are equiphase surfaces are curved as shown in FIG. 11B. Due to the curved wavefronts, reflected light beams are collected.

The effect of the present technology of collecting reflected light beams is particularly effective when a pixel size is smaller than 2 to 3 μm. In addition, the effect is particularly noticeable when a difference between the heights of the reflecting surfaces of the first reflecting plate and the second reflecting plates is lower than or equal to 1 μm.

This is because the continuity of the wave functions becomes conspicuous as the pixel size approaches the wavelength of a light beam (about 0.7 μm in the case of red light).

### (Effect of a Configuration of the Present Technology)

Next, a wave simulation was performed on a configuration of a solid-state imaging device according to an embodiment of the present technology using an FDTD (Finite-Difference Time-Domain) method.

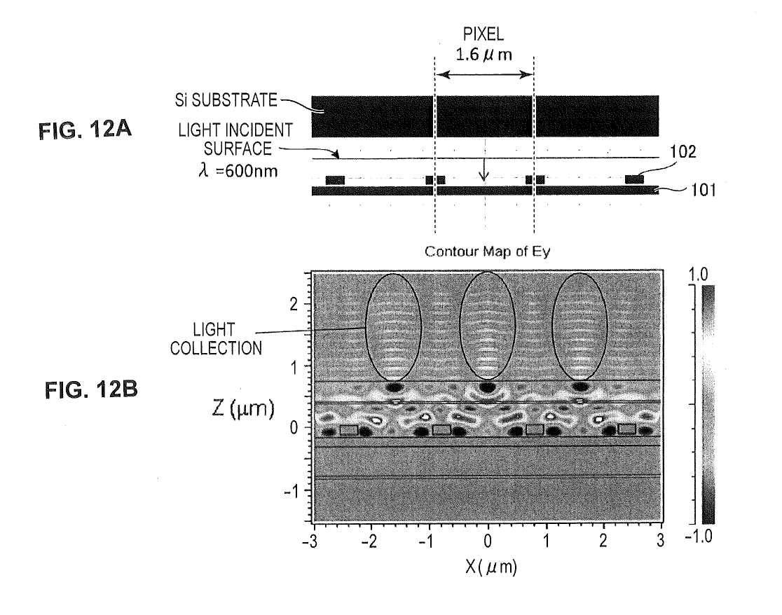

The structure for performing the simulation is shown in FIG. 12A.

As shown in FIG. 12A, by setting a light incident surface to be a horizontal surface (a plane parallel with reflecting surfaces of reflecting plates) below an Si substrate and above the reflecting plates, light having a wavelength λ of 600 nm was set to be emitted in the direction perpendicular to the light incident surface so as to be emitted to the reflecting plates 101 and 102 which are formed of copper (Cu). In addition, the pixel size was set to be 1.6 μm. Under the set conditions, the state of the light reflected on the reflecting plates 101 and 102 was simulated.

The result of the simulation is shown in FIG. 12B. FIG. 12B shows electric field intensity distribution when the state is an equilibrium state after a sufficient time elapses.

Based on the result, it is understood that wavefronts of the reflected light were curved to be a spherical shape, and light collection occurred at the centers of pixels.

The result means that the wavefronts were curved due to a phase difference made from reflection on the level differences of the first reflecting plate 101 and the second reflecting plates 102, and as a result, the light beams were collected.

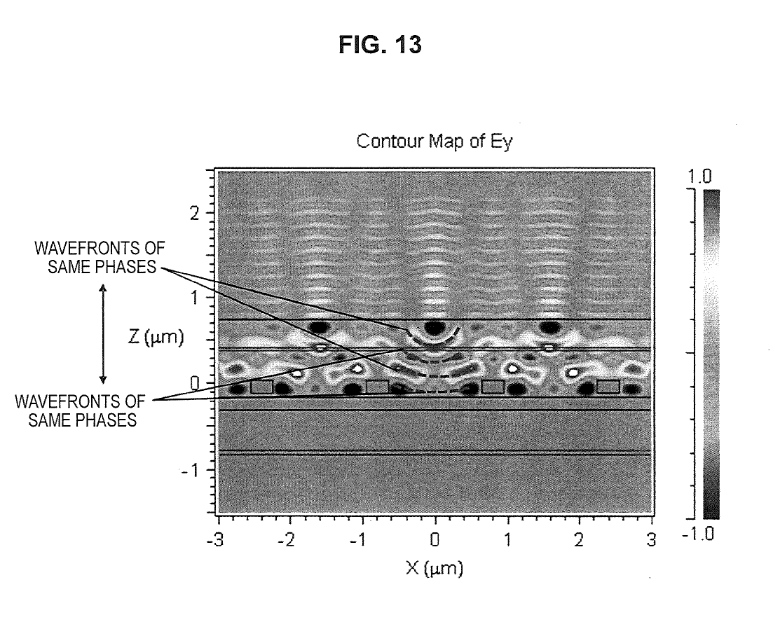

In addition, FIG. 13 shows wavefronts of the same phases indicated by dashed lines using the enlarged diagram of FIG. 12B showing the simulation result.

In the four dashed lines of FIG. 13, the interval of adjacent dashed lines has a phase of substantially π.

As indicated by the dashed lines of FIG. 13, it is understood that the wavefronts are gradually curved in the upper direction, and accordingly, reflected light beams are collected.

### (Specific Example of a Reflecting Plate)

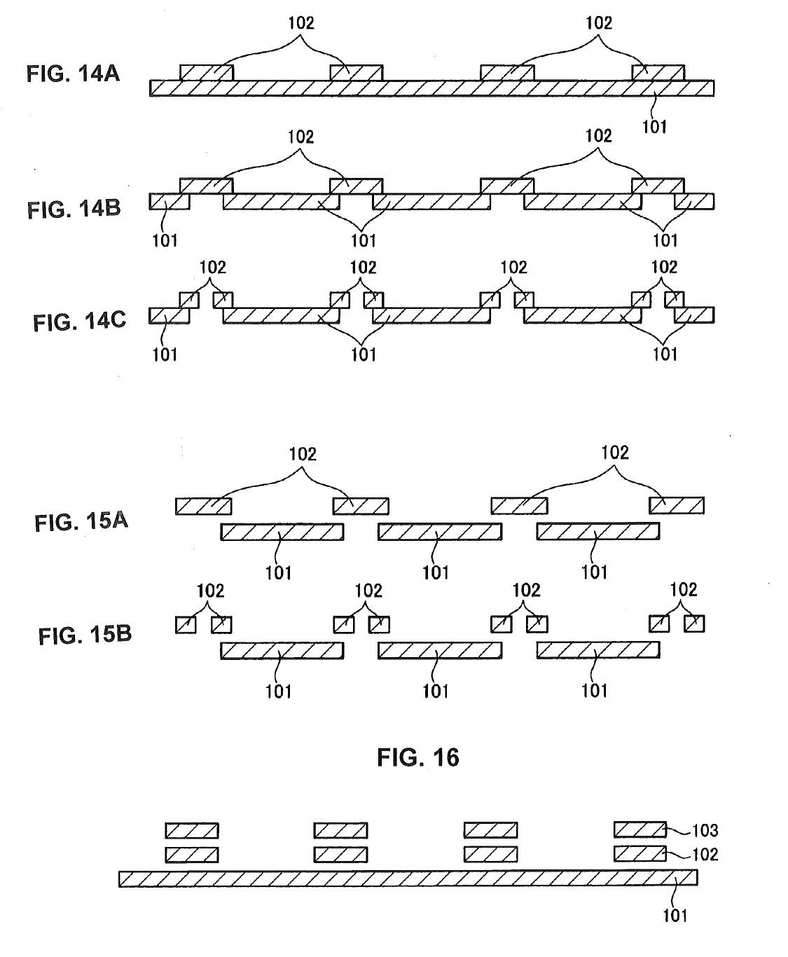

It is understood that reflected light beams can be collected according to the principle and the structure of the reflecting plate as described above, but also in the structures of reflecting plates shown in FIGS. 14A to 18 below, reflected light beams can be collected according to the same principle.

The present technology also includes the structures of the reflecting plates shown in FIGS. 14A to 18 below.

The structures shown in FIGS. 14A to 14C are structures in which projection parts (second reflecting plates 102) of a reflecting plate are present between pixels, and the first reflecting plate 101 of a lower layer and the second reflecting plates 102 of an upper layer are not separated, but stuck to each other.

In the structure shown in FIG. 14A, the first reflecting plate 101 is a flat plate, the second reflecting plates 102 are flat plates, and the first reflecting plate 101 and the second reflecting plates 102 stick to each other.

In the structure shown in FIG. 14B, the first reflecting plates 101 are separated from each other at the edge portions (boundaries) of pixels, and the second reflecting plates 102 are formed in the same manner as in FIG. 14A. The first reflecting plates 101 and the second reflecting plates 102 stick to each other at the edge portions thereof.

In the structure shown in FIG. 14C, the second reflecting plates 102 are separated from each other at the edge portions (boundaries) of pixels, and the first reflecting plates 101 are formed in the same manner as in FIG. 14B. The first reflecting plates 101 and the second reflecting plates 102 stick to each other at the edge portions thereof, and the reflecting plates 101 and 102 are divided in units of pixels.

As shown in the structures of FIGS. 14A to 14C, in the present technology, the reflecting plates in a lower layer and the reflecting plates in an upper layer may be formed to stick to each other, and it is not necessary to separate the upper and lower reflecting plates.

Also in the structures, a phase difference of light beams arises due to reflection on projection parts and reflection on a flat surface below the projection parts, and reflected light beams can be collected at the centers of pixels in the same manner as in a structure in which the upper and lower reflecting plates are separated.

In addition, as shown in the structure shown in FIG. 14C, the same effect can be exhibited even when there are gaps between the projection parts. Furthermore, the same effect can also be exhibited when there are gaps in the surface below the projection parts.

In the structures shown in FIGS. 15A and 15B, first reflecting plates 101 of a lower layer are separated from second reflecting plates 102 of an upper layer, and the first reflecting plates 101 of the lower layer are divided in units of pixels.

In the structure shown in FIG. 15A, the first reflecting plates 101 are flat plates, the second reflecting plates 102 are flat plates, and the first reflecting plates 102 are separated from the second reflecting plates 102 in the top-bottom direction. In addition, the first reflecting plates 101 are divided in units of pixels. Furthermore, the first reflecting plates 101 and the second reflecting plates 102 are disposed so as to exactly fill the gaps between adjacent reflecting plates.

In the structure shown in FIG. 15B, the second reflecting plates 102 are separated from each other at the edge portions (boundaries) of pixels, and the first reflecting plates 101 are formed in the same manner as in FIG. 15A.

The structures shown in FIGS. 15A and 15B can attain an improvement in light reflection efficiency since the second reflecting plates 102 of the upper layer are formed so as to cover the gaps between the first reflecting plates 101 of the lower layer.

In addition, the same effect can be exhibited even when there are gaps between the reflecting plates in the upper layer as shown in the structure of FIG. 15B. In addition, the same effect can be exhibited even when there are gaps between the reflecting plates in the lower layer.

In the structure shown in FIG. 16, reflecting plates form a multi-layer structure, and since a reflectance of one layer is low, the structure is effective when the reflectance is increased.

Here, the reflecting plates are in a three-layer structure with the first reflecting plate 101, second reflecting plates 102, and third reflecting plates 103, but the same effect can be obtained even in a structure with more layers.

In the structure shown in FIG. 16, the second reflecting plates 102 and the third reflecting plates 103 form the “second portions of a reflecting plate” described above.

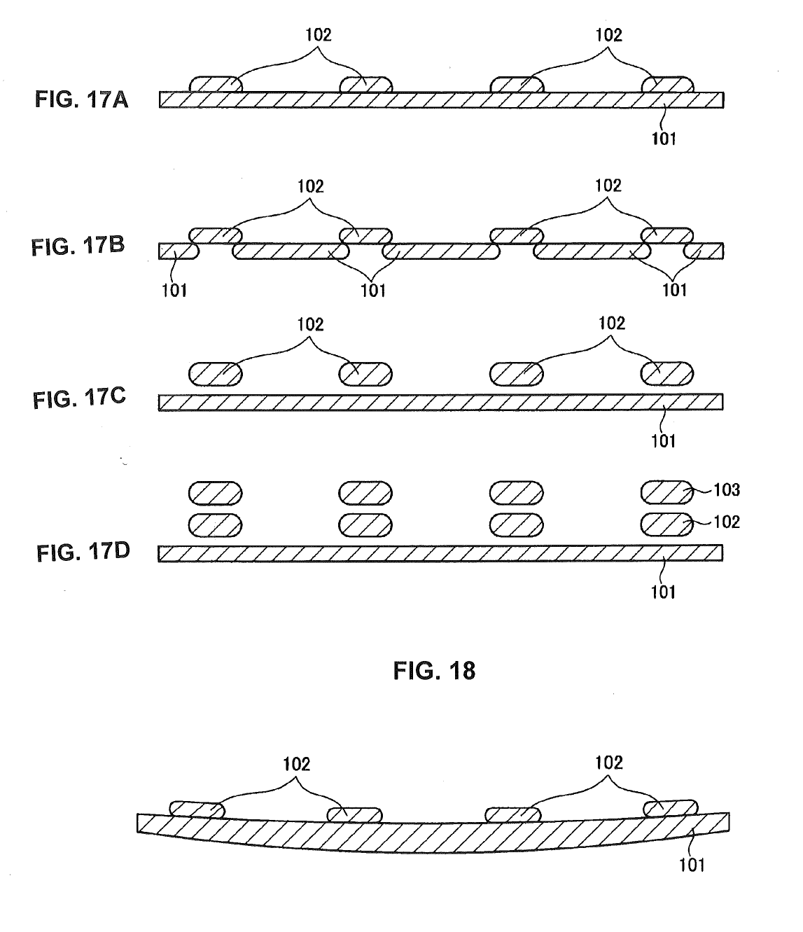

In the structures shown in FIGS. 17A to 17D, reflecting plates of an upper layer are formed to have a shape with angles taken out, rather than a rectangular shape.

In the structure shown in FIG. 17A, the shape of the second reflecting plates 102 in the structure shown in FIG. 14A is changed to the shape with angles taken out from the rectangular shape.

In the structure shown in FIG. 17B, the shapes of the first reflecting plates 101 and the second reflecting plates 102 in the structure shown in FIG. 14B are changed to the shapes with angles taken out from the rectangular shapes.

In the structure shown in FIG. 17C, the shape of the second reflecting plates 102 in the structure shown in FIG. 12A is changed to the shape with angles taken out from the rectangular shape.

In the structure shown in FIG. 17D, the shapes of the second reflecting plates 102 and the third reflecting plates 103 in the structure shown in FIG. 16 are changed to the shapes with angles taken out from the rectangular shapes.

In the present technology, the structure of reflecting plates with angles taken out as in the structures shown in FIGS. 17A to 17D may be possible, and it is not necessary to set the shape of the reflecting plates to be a rectangular shape.

The structure shown in FIG. 18 is formed such that the overall shape of the first reflecting plate 101 in the structure shown in FIG. 17A bends. The upper and lower surfaces of the first reflecting plate 101 are formed to be curved surfaces bending downward. It should be noted that, in the upper and lower surfaces of the first reflecting plate, the lower surface has a more curvature.

In a manufacturing process, producing a flat film is difficult in general, and when the thickness of the reflecting plate is formed to be thin, there are cases in which the upper and lower surfaces of the reflecting plate bend as shown in FIG. 18. In FIG. 18, the curved surfaces are formed to project downward, but there are cases of curved surfaces formed to project upward.

According to the present technology, the same effect is obtained even when the entire reflecting plate bends as in the structure shown in FIG. 18.

Hereinabove, the structures of the reflecting plates in which light beams perpendicularly incident on a substrate are reflected, and collected at the centers of pixels have been described.

Next, a case in which light is obliquely incident on an end of a chip due to a lens system of a solid-state imaging device will be considered.

In such a case, it is difficult to collect light beams at the centers of pixels when the light beams are obliquely incident in the structures shown in FIGS. 14A to 18.

Thus, light beams can be collected at the centers of pixels by arranging reflecting plates in an asymmetric structure.

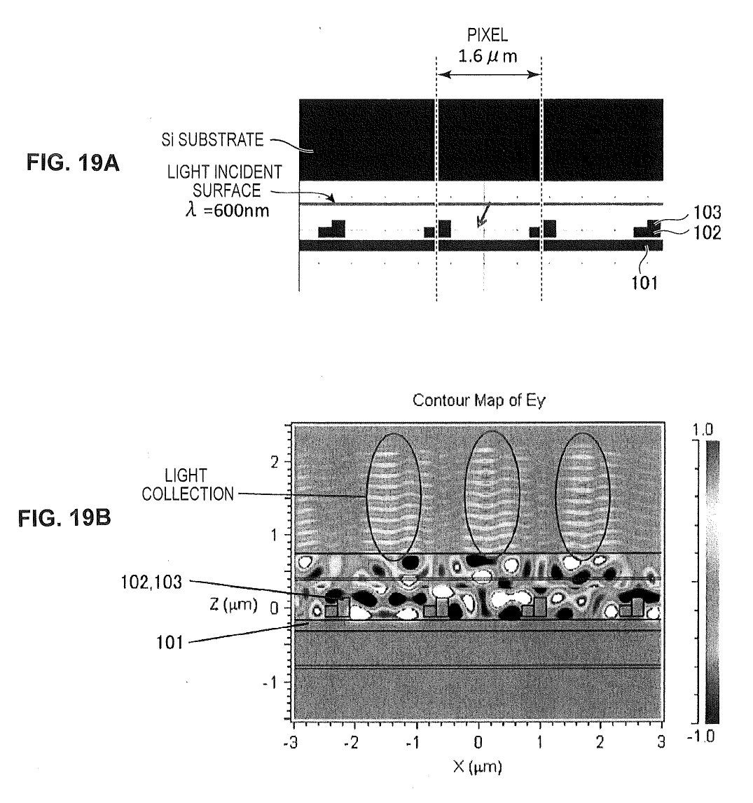

As shown in FIG. 19A, a structure of reflecting plates in which reflecting plates of an upper layer, which are provided at the edge portions of pixels in the upper layer, are formed to be in an asymmetric shape is set. To be specific, in the structure shown in FIG. 19A, the reflecting plates at the edge portions of the pixels are configured such that the second reflecting plates 102 with a wide width and the third reflecting plates 103 with a narrow width are laminated sticking to each other, and the third reflecting plates 103 are formed on the right halves of the second reflecting plates 102. Accordingly, the reflecting plates of the upper layer have a right-left asymmetric shape.

A wave simulation was performed with regard to the structure shown in FIG. 19A using the FDTD method.

A light incident surface was set as a horizontal surface (a flat surface parallel with the reflecting surfaces of the reflecting plates) below a Si substrate and above the reflecting plates in the structure shown in FIG. 19A. Then, light having a wavelength λ of 600 nm was set to be emitted from the light incident surface in the left-lower direction oblique by 5° so as to be emitted to the reflecting plates 101, 102, and 103 made of copper (Cu). Under the set conditions, the state of the light reflected on the reflecting plates 101, 102, and 103 was simulated.

The result of the simulation is shown in FIG. 19B. FIG. 19B shows electric field intensity distribution when the state is in an equilibrium state after a sufficient time elapses.

Based on the result, it is understood that wavefronts of the reflected light were curved to be a spherical shape, light collection occurred at the centers of pixels, and the light was incident substantially perpendicular to the silicon substrate.

The result means that the wavefronts were curved due to the level difference of the first reflecting plate 101 of the lower layer and the reflecting plates 102 and 103 of the upper layer, and the asymmetry of the reflecting plates 102 and 103 of the upper layer, and means, as a result, that light collection and an operation to correct the oblique light incidence should be in the perpendicular direction.

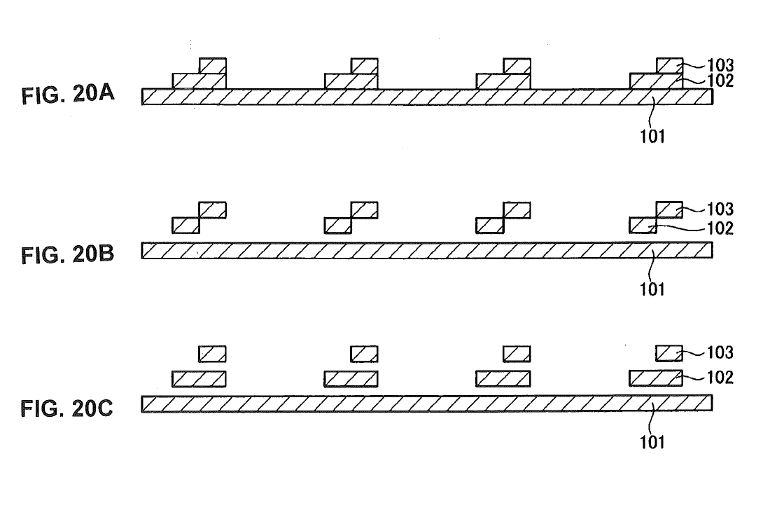

Furthermore, structures of reflecting plates that exhibit the same effect as that of the structure shown in FIG. 19A employing such asymmetric structures of the reflecting plates are shown in FIGS. 20A to 20C.

The structure shown in FIG. 20A is configured such that the first reflecting plate 101 and the second reflecting plates 102 in the structure shown in FIG. 19A are laminated while further sticking to each other.

The structure shown in FIG. 20B is configured such that the widths of the second reflecting plates 102 and the third reflecting plates 103 in the structure shown in FIG. 19A are set to be the same, and the positions of the second reflecting plates 102 and the third reflecting plates 103 are deviated in the right and left directions respectively.

The structure shown in FIG. 20C is configured such that the second reflecting plates 102 and the third reflecting plates 103 in the structure shown in FIG. 19A are separated from each other in the upper-lower directions.

The structures shown in FIGS. 20A to 20C also attain light collection and an operation to correct oblique incidence to be in the perpendicular direction.

In the present technology, a multi-layered film made of a metallic material, an inorganic material, or a resin can be used as the material of reflecting plates.

As metallic materials, for example, Al, Ta, and Ag can be used in addition to Cu that was adopted in the structure in which the simulation of FIG. 12B was performed.

It should be noted that the first reflecting plate 101 of the lower layer and the second reflecting plates 102 and the third reflecting plates 103 of the upper layer may be formed of the same material or of different materials.

When the reflecting plates are formed of different materials, for example, the reflecting plates of the upper layer are considered to be formed of a material with which the reflecting plates are easily formed in a fine pattern, or a material with a satisfactory embedding property into a trench.

In addition, the reflecting plates according to the present technology can also be used as a wiring layer provided on a side of a substrate opposing a light incidence side, in other words, on the side of a surface of a backside illumination structure.

On the side of the surface of the backside illumination structure, circuit elements such as a pixel transistor, a transistor of a peripheral circuit unit, and the like are provided on a substrate, and an electrode wiring for supplying a voltage to electrodes of the circuit elements are provided on the side of the surface rather than the substrate. The reflecting plates can also be used as the wiring layer constituting the electrode wiring.

It should be noted that, separately from the electrode wiring that actually supplies a voltage to the circuit elements, a wiring layer in the same layer as the electrode wiring (a dummy wiring that does not supply a voltage) can be formed so as to be set as a reflecting plate. When this structure is produced, the wiring layer is formed, and patterned, and an electrode wiring and a reflecting plate may each be formed.

Furthermore, a plurality of wiring layers with a multi-layered wiring provided on the side of the surface rather than the substrate in the backside illumination structure can also be used as the reflecting plates 101 of a lower layer and the reflecting plates 102 and 103 of an upper layer.

### (Application of the Reflecting Plate to a Display Device)

The reflecting plate according to the present technology can also be applied to a display device, not being limited to a solid-state imaging device, and an electronic apparatus with the solid-state imaging device.

As the display device to which the reflecting plate according to the present technology is applied, a display device is configured such that light beams are emitted from a light emitting layer not only to the front side but also to the rear side, and colors are diversified for pixels by providing color filters, and the like. For example, an organic EL element having an organic EL layer as a light emitting layer can be applied to a display device with a light emitting unit.

In the configuration in which light is also emitted to the rear side from the light emitting layer, the light emitted to the rear side is reflected to the front side by providing reflecting plates, and thereby, use efficiency of light emitted from the light emitting layer can be enhanced.

In the configuration in which colors are diversified for pixels by providing color filters, and the like, light leaks to adjacent pixels, causing color mixing, and thus, color reproducibility deteriorates. By providing the reflecting plate according to the present technology, reflected light beams can be collected in pixels, reducing light beams leaking to adjacent pixels, and thereby occurrence of color mixing can be suppressed.

### (Modified Example of the Reflecting Plate)

In the description provided hereinabove, the reflecting plate is configured to cause reflected light beams to be collected for each pixel.

The present technology is not limited to the configuration in which reflected light beams are collected in each pixel, and can also be applied to a configuration in which reflected light beams are collected for each region constituted by a plurality of pixels.

### 2. First Embodiment

### Solid-State Imaging Device

Next, specific embodiments of the present technology will be described.

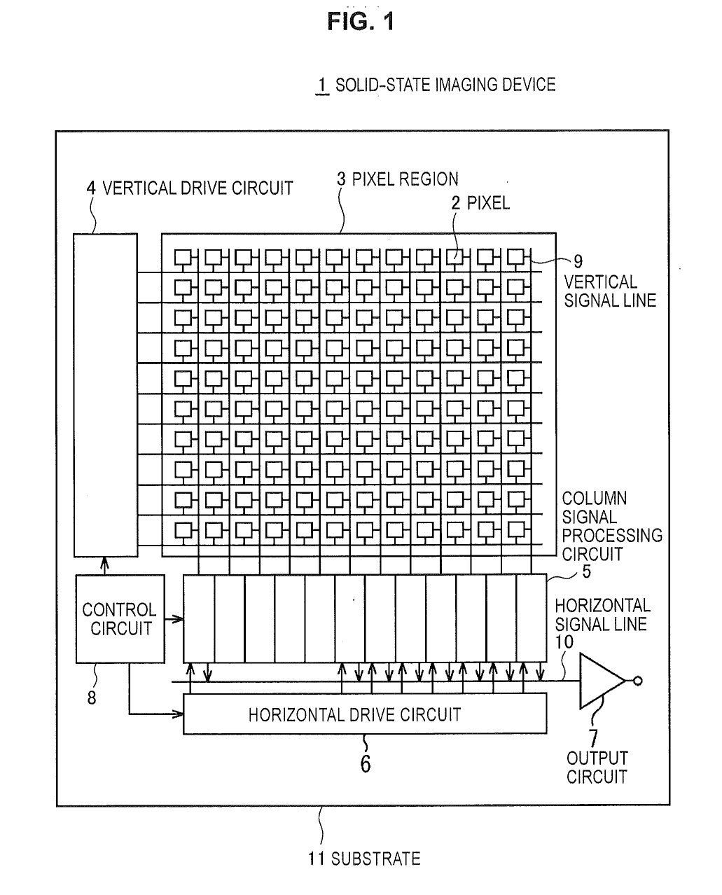

FIG. 1 shows a schematic configuration diagram (plan view) of a solid-state imaging device according to a first embodiment.

In the present embodiment, the present technology is applied to a CMOS image sensor.

As shown in FIG. 1, the solid-state imaging device 1 according to the present technology includes a pixel region 3 constituted by a plurality of pixels 2 arranged on a substrate 11 formed of silicon, a vertical drive circuit 4, column signal processing circuits 5, a horizontal drive circuit 6, an output circuit 7, and a control circuit 8.

The pixels 2 are constituted by photoelectric conversion units formed of photodiodes, and a plurality of pixel transistors, and regularly arranged in plural on the substrate 11 in a two-dimensional array form.

As the pixel transistors constituting the pixels 2, for example, a transfer transistor, a reset transistor, a selecting transistor, and an amplifying transistor are exemplified.

The pixel region 3 is constituted by the plurality of pixels 2 regularly arranged in the two-dimensional array form. The pixel region 3 includes effective pixel regions in which incident light is photoelectrically converted, signal electric charges generated accordingly are amplified, and the signal electric charges are read using the column signal processing circuits 5, and black reference pixel regions (not shown in the drawing) for outputting optical black that serves as a reference of the black level. The black reference pixel regions are generally formed in the outer periphery portions of the effective pixel regions.

The control circuit 8 generates a clock signal, a control signal, and the like that serve as references of operations of the vertical drive circuit 4, the column signal processing circuits 5, the horizontal drive circuit 6, and the like based on vertical synchronization signals, horizontal synchronization signals, and master clocks. Then, the clock signals, the control signals, and the like generated in the control circuit 8 are input to the vertical drive circuit 4, the column signal processing circuits 5, the horizontal drive circuit 6, and the like.

The vertical drive circuit 4 includes, for example, a shift register, and selectively scans each pixel 2 in the pixel region 3 in order in the vertical direction in units of rows. Then, the vertical drive circuit supplies pixel signals based on the signal electric charges generated in the photodiodes of each pixel 2 according to a light sensing amount to the column signal processing circuits 5 through vertical signal lines 9.

The column signal processing circuits 5 are arranged for, for example, each column of the pixels 2, and performs signal processes of noise removal, signal amplification, and the like on signals output from the pixels 2 in one row using signals from the black reference pixel regions (although not shown in the drawing, the regions are formed in the outer peripheral portions of the effective pixel regions) for each pixel column. Horizontal selection switches (not shown in the drawing) are provided between output stages of the column signal processing circuits 5 and a horizontal signal line 10.

The horizontal drive circuit 6 includes, for example, a shift register, selects each of the column signal processing circuits 5 in order by sequentially outputting horizontal scanning pulses, and then outputs pixel signals from each of the column signal processing circuits 5 to the horizontal signal line 10.

The output circuit 7 performs the signal processes on the signals supplied from each of the column signal processing circuits 5 through the horizontal signal line 10, and outputs the signals.

Next, a configuration of each pixel 2 of the solid-state imaging device 1 according to the present embodiment will be described.

The solid-state imaging device 1 according to the present embodiment is a solid-state imaging device with the backside illumination structure having the surface side of a semiconductor substrate as a circuit formation surface, and the rear side of the semiconductor substrate as a light incident surface.

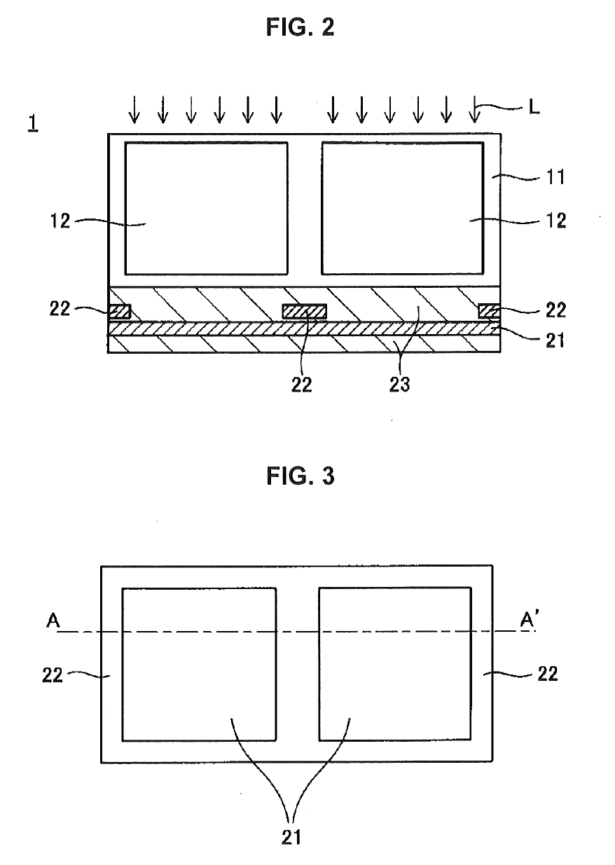

FIG. 2 shows a schematic cross-sectional diagram of the pixel region 3 of the solid-state imaging device 1 according to the present embodiment.

As shown in FIG. 2, in the solid-state imaging device 1 according to the present embodiment, photoelectric conversion units 12 are formed on the substrate 11 such as a silicon substrate, or the like for each pixel.

In addition, the upper surface of the substrate 11 is set to be a light incident surface, and light L is incident on the substrate 11 from above.

Although not shown in the drawing, circuits of pixel transistors, and the like are formed on the lower surface of the substrate 11, that is, the surface opposing the light incident surface.

It should be noted that, in FIG. 2, the configuration of an upper layer above the substrate 11 is not shown in the drawing. In the solid-state imaging device 1 according to the present embodiment, for example, a color filter layer and an on-chip lens can be provided on the upper layer of the substrate 11 in the same manner as in general solid-state imaging devices.

Reflecting plates are provided on the side opposing the light incident surface of the substrate 11 (on the surface side rather than the substrate 11)

In the present embodiment, particularly, employing a two-layered structure having a first reflecting plate 21 of a lower layer and second reflecting plates 22 of an upper layer for the reflecting plate provided on the surface side rather than the substrate 11, the first reflecting plate 21 is formed over all of the pixels to be a flat plate shape, and the second reflecting plates 22 are formed at the edge portions (boundaries) of the pixels.

In addition, the second reflecting plates 22 are formed separately from the first reflecting plate 21, and an insulating layer 23 is also formed between the layers of the reflecting plates 21 and 22.

In other words, the structure of the reflecting plates 21 and 22 according to the present embodiment is substantially the same as that of the reflecting plates 101 and 102 shown in FIG. 12A. In addition, in the present embodiment, the first reflecting plate 21 corresponds to the “first portion of the reflecting plate” described above, and the second reflecting plates 22 correspond to the “second portions of the reflecting plate” described above.

As the material of the reflecting plates 21 and 22, a material such as a metal, or the like having high reflectance can be used. Materials that have been used for reflecting plates in configurations of the related art can also be used.

For example, in addition to Cu that has been adopted in the structure in which the simulation of FIG. 12B is performed, Al, Ta, Ag, or the like can be used as a material of reflecting plates.

Furthermore, the material is not limited to a metal, and a multi-layered film made of an inorganic material, a resin, or the like can be used as long as the material reflects light.

It should be noted that the materials of the first reflecting plate 21 and the second reflecting plates 22 may be the same or different.

The reflecting plates 21 and 22 can be formed using, for example, a vapor deposition method, or a damascene method.

A pixel size and a difference between the heights of reflecting surfaces of the first reflecting plate 21 and the second reflecting plates 22 are decided so that there is a phase difference between reflected light on the first reflecting plate 21 and reflected light on the second reflecting plates 22.

Preferably, the pixel size is configured to be smaller than 2 to 3 μm.

In addition, a difference between the heights of the reflecting surfaces of the first reflecting plate 21 and the second reflecting plates 22 is preferably configured to be 1 μm or less.

Since the phase difference of reflected light on the first reflecting plate 21 and the second reflecting plates 22 can be increased with the configurations, a light collecting effect obtained by the reflecting plates can be enhanced.

Next, FIG. 3 shows a plan layout of the reflecting plates of the solid-state imaging device according to the present embodiment.

FIG. 3 shows a plan structure of the reflecting plates in the cross-sectional diagram showing the structure of pixels of the solid-state imaging device of FIG. 2, and the cross-sectional diagram taken along the line A-A′ in FIG. 3 corresponds to the cross-sectional diagram of the reflecting plates in FIG. 2.

As shown in FIG. 3, the second reflecting plates 22 are formed in the peripheral portion of pixels and inter-pixel portions.

As shown in FIGS. 2 and 3, the reflecting plates are formed to be divided into the first reflecting plate 21 and the second reflecting plates 22 having a level difference, and reflected light beams are collected at the centers of photoelectric conversion units.

For this reason, leakage of light (color mixing) to the photoelectric conversion units 12 of adjacent pixels is reduced, and sensitivity increases.

Furthermore, since a main light beam is gradually obliquely incident toward an edge of a light sensing surface of an image sensor chip, in order to correct an obliquely incident light beam, the reflecting plates may be asymmetrically structured in pixels positioned in locations other than the center of a pixel portion as shown in FIG. 19A, or 20A to 20C.

Accordingly, even when the main light beam is obliquely incident, reflected light beams are collected at the centers of photoelectric conversion units, leakage of light (color mixing) to adjacent photoelectric conversion units (pixels) is reduced, and sensitivity increases.

According to the configuration of the solid-state imaging device 1 of the present embodiment described above, reflecting plates are constituted by a first reflecting plate 21 formed over all of the pixels including the center of the pixels, and the second reflecting plates 22 formed in the boundaries of adjacent pixels in an upper layer (on the incident side) with respect to the first reflecting plate 21.

In addition, reflected light beams are collected within the pixels by generating a phase difference between light beams reflected by the first reflecting plate 21 and light beams reflected by the second reflecting plates 22, and thereby leakage of light to adjacent pixels can be prevented.

Accordingly, sensitivity can be efficiently improved without increasing color mixing caused by such leakage of light to adjacent pixels.

Thus, according to the present embodiment, the solid-state imaging device 1 which has high sensitivity, and obtains satisfactory color reproducibility and image quality can be realized.

### 3. Second Embodiment

### Solid-State Imaging Device

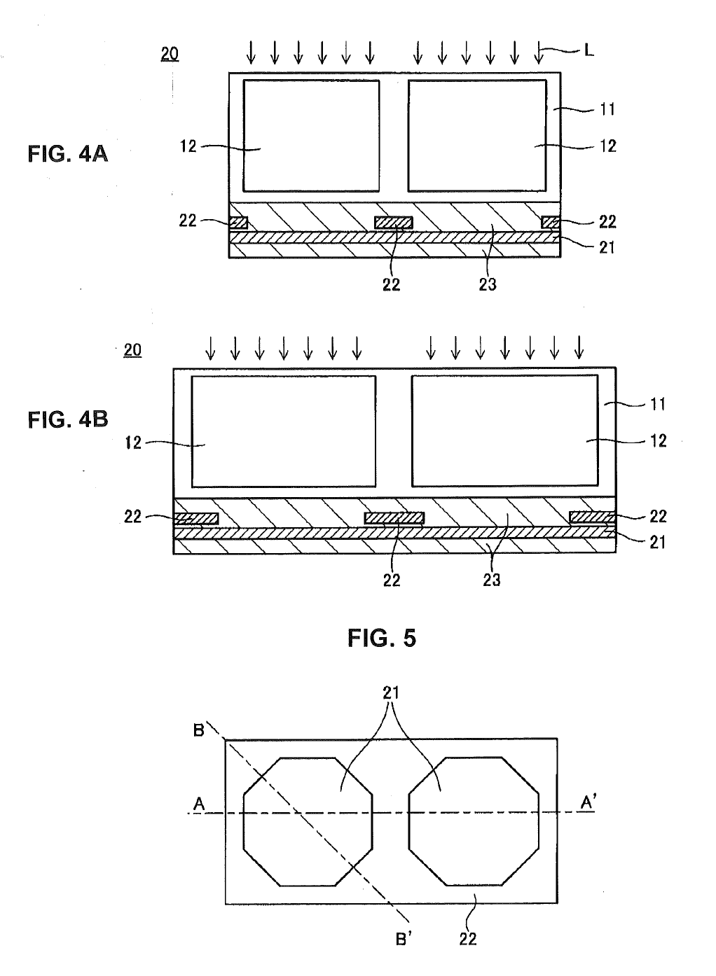

FIGS. 4A, 4B, and 5 show schematic configuration diagrams of a solid-state imaging device 20 according to a second embodiment.

The present embodiment is also of the present technology applied to a CMOS image sensor.

FIGS. 4A and 4B show cross-sectional diagrams of a pixel region, and FIG. 5 shows a plan layout diagram of reflecting plates.

In addition, the solid-state imaging device 20 of the present embodiment is also a solid-state imaging device with the structure of backside illumination.

In the solid-state imaging device 20 of the present embodiment, the reflecting plate is provided on the side opposing the light incident side of the substrate 11 (on the surface side rather than the substrate 11).

In the present embodiment, particularly, employing a two-layered structure having the first reflecting plate 21 of a lower layer and the second reflecting plates 22 of an upper layer for the reflecting plate provided on the surface side rather than the substrate 11, the first reflecting plate 21 is formed over all of the pixels to be a flat plate shape, and the second reflecting plates 22 are formed at the edge portions (boundaries) of the pixels.

In addition, the second reflecting plates 22 are formed separately from the first reflecting plate 21, and the insulating layer 23 is also formed between the layers of the reflecting plates 21 and 22.

In other words, the structure of the reflecting plates 21 and 22 according to the present embodiment is substantially the same as that of the reflecting plates 101 and 102 shown in FIG. 12A. In addition, in the present embodiment, the first reflecting plate 21 corresponds to the “first portion of the reflecting plate” described above, and the second reflecting plates 22 correspond to the “second portions of the reflecting plate” described above.

As the material of the reflecting plates 21 and 22, a material such as a metal, or the like having high reflectance can be used. Materials that have been used for reflecting plates in configurations of the related art can also be used.

For example, in addition to Cu that has been adopted in the structure in which the simulation of FIG. 12B is performed, Al, Ta, Ag, or the like can be used as a material of reflecting plates.

Furthermore, the material is not limited to a metal, and a multi-layered film made of an inorganic material, a resin, or the like can be used as long as the material reflects light.

It should be noted that the materials of the first reflecting plate 21 and the second reflecting plates 22 may be the same or different.

The reflecting plates 21 and 22 can be formed using, for example, a vapor deposition method, or a damascene method.

A pixel size and a difference between the heights of reflecting surfaces of the first reflecting plate 21 and the second reflecting plates 22 are decided so that there is a phase difference between reflected light on the first reflecting plate 21 and reflected light on the second reflecting plates 22.

Preferably, the pixel size is configured to be smaller than 2 to 3 μm.

In addition, a difference between the heights of the reflecting surfaces of the first reflecting plate 21 and the second reflecting plates 22 is preferably configured to be 1 μm or less.

Since the phase difference of reflected light on the first reflecting plate 21 and the second reflecting plates 22 can be increased with the configurations, a light collecting effect obtained by the reflecting plates can be enhanced.

Furthermore, in the present embodiment, the second reflecting plates 22 are set to be longer in the diagonal direction of pixels than in the horizontal direction of the pixels as shown in the cross-sectional diagrams of FIGS. 4A and 4B and the plan layout of FIG. 5. As understood from the comparison between FIGS. 4A and 4B, the lengths of the pixels in the diagonal direction are set to be longer than the length thereof in the horizontal direction, and thus, by setting the second reflecting plates 22 to be longer in the diagonal direction, reflected light beams can be collected more at the centers of the photoelectric conversion units 12. Accordingly, color mixing can be further suppressed, and thereby sensitivity can increase.

Furthermore, since a main light beam is gradually obliquely incident toward an edge of a light sensing surface of an image sensor chip, in order to correct an obliquely incident light beam, the reflecting plates may be asymmetrically structured in pixels positioned in locations other than the center of a pixel portion as shown in FIG. 19A, or 20A to 20C.

Accordingly, even when the main light beam is obliquely incident, reflected light beams are collected at the centers of photoelectric conversion units, leakage of light (color mixing) into adjacent photoelectric conversion units (pixels) is reduced, and sensitivity increases.

Since other configurations are the same as those of the solid-state imaging device 1 of the first embodiment, overlapping description will be omitted by providing the same reference numerals.

In the present embodiment, a plan structure of the solid-state imaging device 20 can be the same as that shown in FIG. 1.

According to the configuration of the solid-state imaging device 20 of the present embodiment described above, reflecting plates are constituted by a first reflecting plate 21 formed over all of the pixels including the center of the pixels, and the second reflecting plates 22 formed on the boundaries of adjacent pixels of an upper layer (on the incident side) with respect to the first reflecting plate 21.

In addition, reflected light beams are collected within the pixels by generating a phase difference between light beams reflected by the first reflecting plate 21 and light beams reflected by the second reflecting plates 22, and thereby leakage of light to adjacent pixels can be prevented.

Accordingly, sensitivity can be efficiently improved without increasing color mixing caused by such leakage of light to adjacent pixels.

Thus, according to the present embodiment, the solid-state imaging device 20 which has high sensitivity and obtains satisfactory color reproducibility and image quality can be realized.

### 4. Third Embodiment

### Solid-State Imaging Device

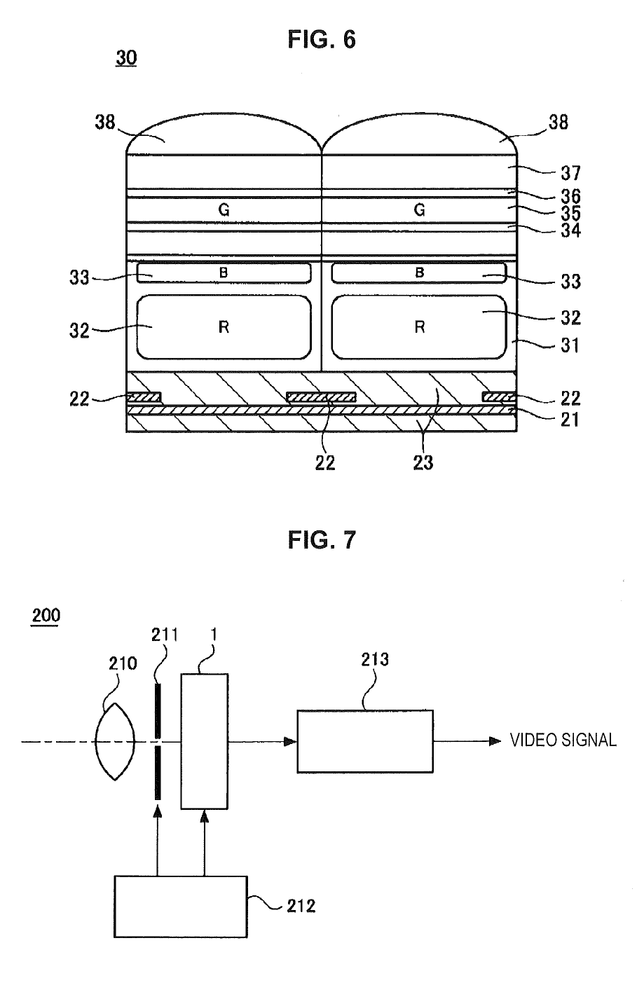

FIG. 6 shows a schematic configuration diagram (cross-sectional diagram) of a solid-state imaging device 30 of a third embodiment.

In addition, the solid-state imaging device 30 of the present embodiment is also a solid-state imaging device with the structure of backside illumination.

As shown in FIG. 6, in the solid-state imaging device 30 of the present embodiment, photoelectric conversion units of three layers having different spectral characteristics of three colors of RGB are stacked in the vertical direction.

With regard to the photoelectric conversion units in the two lower layers, a photoelectric conversion unit 32 of red R and a photoelectric conversion unit 33 of blue B are formed within a substrate 31 such as a silicon substrate from the bottom. The photoelectric conversion units 32 and 33 respectively sense red light and blue light using great wavelength dependency of absorption coefficients.

In addition, a photoelectric conversion unit of green G at the top layer is formed to be an organic photoelectric conversion film 35 which mainly senses green light in a structure in which the organic photoelectric conversion film 35 is sandwiched between a transparent electrode 34 of a lower layer (lower electrode) and another transparent electrode 36 of an upper layer (upper electrode).

On-chip lenses 38 are formed over the transparent electrode 36 of the upper layer (upper electrode) of the photoelectric conversion film 35 via an insulating layer 37.

In addition, a reflecting plate is provided on the side opposing the light incident side of the substrate 31 (on the surface side rather than the substrate 31).

In the present embodiment, particularly, employing a two-layered structure having the first reflecting plate 21 of a lower layer and the second reflecting plates 22 of an upper layer for the reflecting plate provided on the surface side rather than the substrate 31, the first reflecting plate 21 is formed over the entire pixels to be a flat plate shape, and the second reflecting plates 22 are formed at the edge portions (boundaries) of the pixels.

In addition, the second reflecting plates 22 are formed separately from the first reflecting plate 21, and the insulating layer 23 is also formed between the layers of the reflecting plates 21 and 22.

In other words, the structure of the reflecting plates 21 and 22 according to the present embodiment is substantially the same as that of the reflecting plates 101 and 102 shown in FIG. 12A. In addition, in the present embodiment, the first reflecting plate 21 corresponds to the “first portion of the reflecting plate” described above, and the second reflecting plates 22 corresponds to the “second portions of the reflecting plate” described above.

As the material of the reflecting plates 21 and 22, a material such as a metal, or the like having high reflectance can be used. Materials that have been used for reflecting plates in configurations of the related art can also be used.

For example, in addition to Cu that has been adopted in the structure in which the simulation of FIG. 12B is performed, Al, Ta, Ag, or the like can be used as a material of reflecting plates.

Furthermore, the material is not limited to a metal, and a multi-layered film made of an inorganic material, a resin, or the like can be used as long as the material reflects light.

It should be noted that the materials of the first reflecting plate 21 and the second reflecting plates 22 may be the same, or different.

The reflecting plates 21 and 22 can be formed using, for example, a vapor deposition method, or a damascene method.

A pixel size and a difference between the heights of reflecting surfaces of the first reflecting plate 21 and the second reflecting plates 22 are decided so that there is a phase difference between reflected light on the first reflecting plate 21 and reflected light on the second reflecting plates 22.

Preferably, the pixel size is configured to be smaller than 2 to 3 μm.

In addition, a difference between the heights of the reflecting surfaces of the first reflecting plate 21 and the second reflecting plates 22 is preferably configured to be 1 μm or less.

Since the phase difference of reflected light by the first reflecting plate 21 and the second reflecting plates 22 can be increased with the configurations, a light collecting effect obtained by the reflecting plates can be enhanced.

Furthermore, since a main light beam is gradually obliquely incident toward an edge of a light sensing surface of an image sensor chip, in order to correct an obliquely incident light beam, the reflecting plates may be asymmetrically structured in pixels positioned in locations other than the center of a pixel portion as shown in FIG. 19A, or 20A to 20C.

Accordingly, even when the main light beam is obliquely incident, reflected light beams are collected at the centers of photoelectric conversion units, leakage of light (color mixing) to adjacent photoelectric conversion units (pixels) is reduced, and sensitivity increases.

In the solid-state imaging device 30 according to the present embodiment, the same configuration as the plan layout of the first embodiment shown in FIG. 3 or the plan layout of the second embodiment shown in FIG. 5 can be employed for a plan layout of the reflecting plates 21 and 22.

According to the configuration of the solid-state imaging device 30 of the present embodiment described above, reflecting plates are constituted by a first reflecting plate 21 formed over all of the pixels including the center of the pixels, and the second reflecting plates 22 formed in the boundaries of adjacent pixels of an upper layer (on the incident side) with respect to the first reflecting plate 21.

In addition, reflected light beams are collected within the pixels by generating a phase difference between light beams reflected by the first reflecting plate 21 and light beams reflected by the second reflecting plates 22, and thereby leakage of light to adjacent pixels can be prevented.

Accordingly, sensitivity can be efficiently improved without increasing color mixing caused by such leakage of light to adjacent pixels.

Thus, according to the present embodiment, the solid-state imaging device 30 which has high sensitivity, and obtains satisfactory color reproducibility and image quality can be realized.

In a solid-state imaging device of the related art in which a plurality of photoelectric conversion units are stacked in the vertical direction, since a red light beam is incident on and absorbed even in a photoelectric conversion unit for green light or a photoelectric conversion unit for blue light, sensitivity to red light is lowered.

On the other hand, in the solid-state imaging device 30 of the present embodiment, since a light beam that has passed through the substrate 31 can be reflected on the reflecting plates 21 and 22, and can return to the photoelectric conversion unit 32 for red light R, sensitivity to red light can be enhanced.

It should be noted that, in the embodiments described above, the first reflecting plate 21 is formed over the entire pixels, but there may be gaps in the first reflecting plate on the boundaries of pixels as in the structure shown in FIGS. 15A and 15B.

In addition, in the embodiments described above, the structure in which the first reflecting plate 21 and the second reflecting plates 22 are separated into two layers is employed, but the structure in which the two layers stick to each other as in the structure shown in FIGS. 14A to 14C, or a structure with three or more layers as in the structure shown in FIG. 16 may be employed.

In addition, a structure in which angles of reflecting plates are taken out as in the structure shown in FIG. 17 or reflecting plates are curved as in the structure shown in FIG. 18 may be employed.

Furthermore, in the embodiment described above, the reflecting plates 21 and 22 may also be used as wiring layers. Particularly, there are many cases in a CMOS image sensor in which a plurality of wiring layers are formed, but the reflecting plates 21 and 22 may also be used as the plurality of wiring layers.

In the embodiments described above, the reflecting plates are configured to collect reflected light beams for each pixel.

The present technology is not limited to the configuration in which reflected light beams are collected for each pixel, and can also be configured to collect light beams for each region in which a plurality of pixels are included.

When the present technology is applied to a solid-state imaging device in which the colors of color filters are the same in four pixels constituted by 2 pixels in the vertical direction×2 pixels in the horizontal direction, for example, reflecting plates may be configured to collect reflected light beams for each region of 4 pixels by providing convex portions of the second reflecting plates 22, or the like on the boundary of regions of 4 pixels.

It should be noted that reflecting plates can be configured to collect reflected light beams for each pixel even in the solid-state imaging device in which the colors of color filters are the same in four pixels constituted by 2 pixels in the vertical direction×2 pixels in the horizontal direction, and such collecting of light beams for each pixel attains high resolution.

### 5. Fourth Embodiment

### Electronic Apparatus with a Solid-State Imaging Device

Next, as a fourth embodiment, an embodiment of an electronic apparatus with a solid-state imaging device will be described.

FIG. 7 shows a schematic configuration diagram (block diagram) of the electronic apparatus of the fourth embodiment.

As shown in FIG. 7, the electronic apparatus 200 of the present embodiment has the solid-state imaging device 1 of the first embodiment, an optical lens 210, a shutter device 211, a drive circuit 212, and a signal processing circuit 213.

The optical lens 210 causes image light (incident light) from a subject to form an image on an imaging plane of the solid-state imaging device 1. Accordingly, signal electric charges are accumulated in the solid-state imaging device 1 for a certain period of time.

The shutter device 211 controls a light radiation period and a light blocking period of the solid-state imaging device 1.

The drive circuit 212 supplies drive signals for controlling transfer operations of signal electric charges and shutter operations of the shutter device 211 in the solid-state imaging device 1. Signals are transferred in the solid-state imaging device 1 with the drive signals (timing signals) supplied from the drive circuit 212.

The signal processing circuit 213 performs various signal processes. Video signals that have undergone signal processes are stored in a storage medium such as a memory, or output to a monitor.

Since miniaturization of pixels in the solid-state imaging device 1 is attained in the electronic apparatus 200 of the present embodiment, downsizing and high resolution of the electronic apparatus 200 are attained. In addition, since simultaneous exposure of all pixels is possible and a high S/N ratio is obtained in the solid-state imaging device 1, image quality can be enhanced.

The electronic apparatus 200 to which the solid-state imaging device 1 can be applied is not limited to digital video cameras, and imaging devices such as digital still cameras, and camera modules for mobile devices such as mobile telephones are possible.

In the electronic apparatus of the present embodiment described above, the solid-state imaging device 1 of the first embodiment is used as a solid-state imaging device.

The electronic apparatus of the present technology is not limited to the configuration in which the solid-state imaging device 1 of the first embodiment is used, and can use an arbitrary solid-state imaging device as long as the device is the solid-state imaging device according to the present technology.

In addition, the configuration of the electronic apparatus of the present technology is not limited to the configuration shown in FIG. 7, and can employ a configuration other than that shown in FIG. 7 as long as the apparatus uses the solid-state imaging device according to the present embodiment.

### 6. Fifth Embodiment

### Display Device

As a fifth embodiment, an embodiment of a display device will be described.

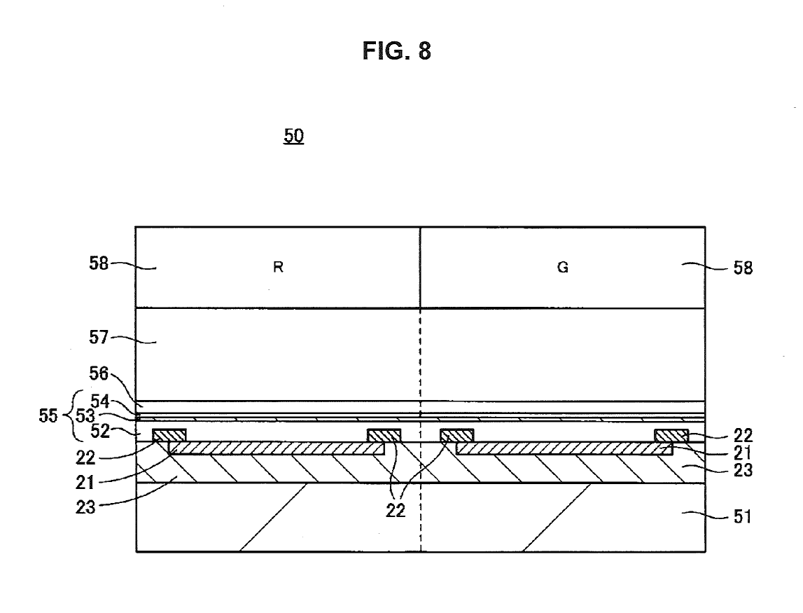

FIG. 8 shows a schematic configuration diagram (cross-sectional diagram) of the display device of the fifth embodiment.

In the embodiment, the present technology is applied to an organic EL display that emits white light using an organic EL element for a light emitting unit thereof.

As shown in FIG. 8, this display device 50 has a substrate 51, an organic EL layer 55, a transparent electrode layer 56, an insulating layer 57, and color filters 58.

The organic EL layer 55 is constituted by an organic layer 52 of a lower layer, a light emitting layer 53, and another organic layer 54 of an upper layer.

The organic layer 52 of the lower layer and the organic layer 54 of the upper layer include an electron implantation layer, an electron transfer layer, a hole transfer layer, a hole implantation layer, and the like.

The light emitting layer 53 includes a light emitting material. The layer is obtained by, for example, doping a guest compound having a light emitting property in a host material.

The organic EL layer 55 constitutes the organic EL element that serves as the light emitting unit.

The color filters 58 are formed for each pixel of the display device 50, and a color filter for red light R is formed on the left pixel and a color filter for green light G is formed on the right pixel in FIG. 8. It should be noted that a color filter for blue light B is formed on a pixel not shown.

As described above, since white light emitted and projected from the light emitting layer 53 is separated into different colors by the color filters 58 in each pixel, color display is possible.

In such a display device, when light is obliquely incident and passes through a filter of an adjacent pixel, color mixing occurs, and thereby color reproducibility deteriorates.

Since light projected from the light emitting layer 53 advances not only in the front direction but also in the rear direction, light loss is caused.

In the display device 50 of the present embodiment, reflecting plates including the first reflecting plates 21 and the second reflecting plates 22 are provided in the backside of the organic EL layer 55 that includes the light emitting layer 53 as shown in FIG. 8.

In the structure of the reflecting plates, the second reflecting plates 22 that are projection parts are positioned between pixels, the first reflecting plates 21 and the second reflecting plates 22 respectively have gaps between pixels, and the first reflecting plates 21 come into contact with the second reflecting plates 22 as shown in FIG. 8.

In other words, the reflecting plates of the present embodiment have the same structure as shown in FIG. 14C. In addition, in the present embodiment, the first reflecting plates 21 correspond to the “first portion of a reflecting plate” described above and the second reflecting plates 22 correspond to the “second portion of a reflecting plate” described above.

In addition, the reflecting plates 21 and 22 come into contact with the organic layer 52 of the organic EL layer 55, and serve as electrodes for the organic EL layer 55 and as reflecting plates.

As materials for the reflecting plates 21 and 22, a material such as a metal is preferable, and Al can be preferably used. As another metal material, for example, Cu, Ta, Ag, or the like can be used.

A pixel size and a difference between the heights of reflecting surfaces of the first reflecting plates 21 and the second reflecting plates 22 are decided so that there is a phase difference between reflected light on the first reflecting plates 21 and reflected light on the second reflecting plates 22.

Preferably, the pixel size is configured to be smaller than 2 to 3 μm.

In addition, a difference between the heights of the reflecting surfaces of the first reflecting plates 21 and the second reflecting plates 22 is preferably configured to be 1 μm or less.

Since the phase difference of reflected light on the first reflecting plates 21 and the second reflecting plates 22 can be increased with the configurations, a light collecting effect obtained by the reflecting plates can be enhanced.

In the configuration of the display device 50 according to the present embodiment described above, the reflecting plates provided on the backside of the organic EL layer 55 are constituted by the first reflecting plates 21 formed at the centers of pixels, and the second reflecting plates 22 formed on the boundary of adjacent pixels and on the light incident side with respect to the first reflecting plates 21.

In addition, reflected light beams are collected within pixels due to the phase difference generated between reflected light on the first reflecting plates 21 and reflected light on the second reflecting plates 22.

In other words, since light beams emitted from the light emitting layer 53 of the organic EL layer 55 are reflected by the reflecting plates 21 and 22 so as to be collected, the light beams can be projected in one direction, and can be made to pass through the color filters 58 without leaking to adjacent pixels.

Accordingly, color mixing caused by light incident on adjacent pixels can be prevented, and use efficiency of light emitted from the light emitting unit can be enhanced.

Thus, according to the present embodiment, the display device 50 that can display images with high use efficiency of light, and satisfactory color reproducibility and image quality can be realized.

A display device according to the present technology such as the display device 50 of the present embodiment, or the like can be applied to a head-mount display in which an organic EL element, or the like is used in a display panel (refer to, for example, International Patent Publication No. 2005/093493 and Japanese Unexamined Patent Application Publication No. 2012-141461).

With the application of the display device according to an embodiment of the present technology to the head-mount display, images with satisfactory color reproducibility and image quality can be displayed without causing color mixing.

The display device of the present embodiment described above is set to be configured to have color filters 58 for each pixel and the light emitting layer 53 of the organic EL layer 55 projecting white light, but the display device of the present technology can also employ another configuration. For example, the present technology can be applied to a display device that is configured to use an element other than the organic EL element for the light emitting unit having the light emitting layer.

It should be understood by those skilled in the art that various modifications, combinations, sub-combinations and alterations may occur depending on design requirements and other factors insofar as they are within the scope of the appended claims or the equivalents thereof.

Additionally, the present technology may also be configured as below.

(1) A solid-state imaging device including:

a photoelectric conversion unit; and

a reflecting plate that includes a first portion that is provided on a side opposing a light incidence side with respect to the photoelectric conversion unit and formed at a center of a region in which light beams are collected, and a second portion that is formed on a boundary of adjacent regions to be convex on the incidence side with respect to the first portion, and collects reflected light beams within the regions by generating a phase difference between reflected light beams on the first portion and reflected light beams on the second portion.

(2) The solid-state imaging device according to (1), wherein the region in which light beams are collected is one pixel.
(3) The solid-state imaging device according to (1) or (2), wherein the second portion is asymmetrically formed in a location other than a center of a chip, and the second portion is formed deviating toward the center of the chip as it gets closer to an edge of the chip.
(4) The solid-state imaging device according to any one of (1) to (3), wherein the first portion or the second portion of the reflecting plate also serves as a wiring layer.
(5) The solid-state imaging device according to any one of (1) to (4), wherein a plurality of the photoelectric conversion units are vertically stacked.
(6) An electronic apparatus including:

an optical lens;

the solid-state imaging device according to any one of (1) to (5); and

a signal processing circuit that processes a signal output from the solid-state imaging device.

(7) A display device including:

a light emitting unit, and

a reflecting plate that is provided on the back side of the light emitting unit, includes a first portion formed at a center of a region in which light beams are collected and a second portion that is formed on a boundary of adjacent regions to be convex on a side of the light emitting unit with respect to the first portion, and causes reflected light beams to be collected within the regions so as to be projected in front of the light emitting unit by generating a phase difference between reflected light beams on the first portion and reflected light beams on the second portion.

(8) The display device according to (7), wherein the region in which light beams are collected is one pixel.
(9) The display device according to (8), wherein a color filter is provided for each of the pixels on the front side of the light emitting unit.
(10) The display device according to any one of (7) to (9), wherein an organic EL element is used for the light emitting unit.

The present technology is not limited to the above-described embodiments, and can employ various configurations within the scope not departing from the gist of the present technology.

The present disclosure contains subject matter related to that disclosed in Japanese Priority Patent Application JP 2012-196439 filed in the Japan Patent Office on Sep. 6, 2012, the entire content of which is hereby incorporated by reference.

What is claimed is:

1. A solid-state imaging device comprising:
a photoelectric conversion unit; and
a reflecting plate that includes a first portion that is provided on a side opposing a light incidence side with respect to the photoelectric conversion unit and formed at a center of a region in which light beams are collected, and a second portion that is formed on a boundary of adjacent regions to be convex on the incidence side with respect to the first portion, and collects reflected light beams within the regions by generating a phase difference between reflected light beams on the first portion and reflected light beams on the second portion.

2. The solid-state imaging device according to claim 1, wherein the region in which light beams are collected is one pixel.

3. The solid-state imaging device according to claim 1, wherein the second portion is asymmetrically formed in a location other than a center of a chip, and the second portion is formed deviating toward the center of the chip as it gets closer to an edge of the chip.

4. The solid-state imaging device according to claim 1, wherein the first portion or the second portion of the reflecting plate also serves as a wiring layer.

5. The solid-state imaging device according to claim 1, wherein a plurality of the photoelectric conversion units are vertically stacked.

6. An electronic apparatus comprising:
an optical lens;
a solid-state imaging device that has a photoelectric conversion unit and a reflecting plate that includes a first portion that is provided on a side opposing a light incidence side with respect to the photoelectric conversion unit and formed at a center of a region in which light beams are collected, and a second portion that is formed on a boundary of adjacent regions to be convex on the incidence side with respect to the first portion, and collects reflected light beams within the regions by generating a phase difference between reflected light beams on the first portion and reflected light beams on the second portion; and
a signal processing circuit that processes a signal output from the solid-state imaging device.

7. A display device comprising:
a light emitting unit, and
a reflecting plate that is provided on the back side of the light emitting unit, includes a first portion formed at a center of a region in which light beams are collected and a second portion that is formed on a boundary of adjacent regions to be convex on a side of the light emitting unit with respect to the first portion, and causes reflected light beams to be collected within the regions so as to be projected in front of the light emitting unit by generating a phase difference between reflected light beams on the first portion and reflected light beams on the second portion.

8. The display device according to claim 7, wherein the region in which light beams are collected is one pixel.

9. The display device according to claim 8, wherein a color filter is provided for each of the pixels on the front side of the light emitting unit.

10. The display device according to claim 7, wherein an organic EL element is used for the light emitting unit.
